(19) United States
(12) Patent Application Publication
(10) Pub. No.: US 2024/0195358 A1
(43) Pub. Date: Jun. 13, 2024

(54) OSCILLATION CIRCUIT

(71) Applicant: LAPIS Technology Co., Ltd., Yokohama (JP)

(72) Inventor: Seiichiro SASAKI, Yokohama (JP)

(73) Assignee: LAPIS Technology Co., Ltd., Yokohama (JP)

(21) Appl. No.: 18/533,178

(22) Filed: Dec. 8, 2023

(30) Foreign Application Priority Data
Dec. 13, 2022 (JP) 2022-198863

(51) Int. Cl. H03B 5/04; H03B 5/24

(52) U.S. Cl. CPC H03B 5/04; H03B 5/24

(57) ABSTRACT

The disclosure allows the temperature characteristics of the oscillation frequency of an oscillation circuit to be adjusted by a simple means. The oscillation circuit includes a first inverter configured so that temperature characteristics of a threshold voltage are adjustable; and a resistance element and a capacitor electrically connected to an input end and an output end of the first inverter, respectively.

### CROSS-REFERENCE TO RELATED APPLICATION

This application claims the priority benefits of Japanese application no. 2022-198863, filed on Dec. 13, 2022. The entirety of the above-mentioned patent application is hereby incorporated by reference herein and made a part of this specification.

### BACKGROUND

### Technical Field

The disclosure relates to an oscillation circuit.

### Description of Related Art

The following technologies are known as technologies related to oscillation circuits. For example, Patent Document 1 (Japanese Patent Application Laid-Open No. 2002-33644) describes a micropower resistance capacitance (RC) oscillator, including: a drive power supply circuit means that uses a current source and a load having contradictory characteristics against temperature changes to obtain a reference signal with a voltage level stable against temperature changes and increases the current fan-out capability of this reference signal to generate a drive power supply; and an RC oscillation circuit means that includes a large number of inverter circuits connected in series, each of which is driven by receiving the drive power supply from the drive power supply circuit means, and an RC circuit having a variable resistor inserted between the output end of the foremost inverter connected to the output end and the input end of the rearmost inverter to form a closed loop and a capacitor inserted between the input end of the rearmost inverter, the connection node of the variable resistor, and the input end of the foremost inverter. The variable resistor has a size set variably according to resistance value data supplied from the outside, and is constructed by combining resistance elements having mutually contradictory characteristics against temperature changes at a predetermined ratio. An oscillation signal that oscillates at a frequency determined by a time constant of the RC circuit appears at the output end.

In Patent Document 2 (Japanese Patent No. 5882606), an oscillation circuit includes: a bandgap circuit that outputs a voltage with reduced temperature dependence; a voltage-current conversion circuit that includes a first variable resistor whose resistance value is changed to a first setting value when it is necessary to keep the oscillation frequency constant and whose resistance value is changed to a second setting value higher than the first setting value when it is not necessary to keep the oscillation frequency constant, converts the voltage output from the bandgap circuit into a current obtained by dividing the voltage by the resistance value of the first variable resistor, and outputs a bias current with the same amount of current as the converted current; and a capacitance resistance (CR) oscillation circuit that includes a second variable resistor whose resistance value is changeable, a capacitor, and a comparator which compares the input voltage with a predetermined reference voltage and switches the output voltage according to the comparison result, in which the response speed of the comparator is controlled according to the current amount of the bias current input from the voltage-current conversion circuit, and the CR oscillation circuit oscillates at an oscillation frequency determined by the resistance value of the second variable resistor, the capacitance value of the capacitor, and the current amount of the bias current.

The temperature characteristics of the oscillation frequency of an oscillation circuit, which includes a plurality of inverters, resistance elements, and capacitors connected in series, depend on the temperature characteristics of the resistance elements and the capacitors. While the temperature characteristics of a general capacitor are flat, the temperature characteristics of a resistance element fluctuate by several percent within an operating temperature range (for example, −40° ° C. to 120° C.). If the temperature characteristics of the resistance element are directly reflected in the temperature characteristics of the oscillation frequency, the oscillation frequency may fluctuate by several percent within the operating temperature range. Therefore, this type of oscillation circuit is not suitable for use in applications (for example, communication applications) that have strict requirements for the temperature characteristics of the oscillation frequency.

In view of the above, the disclosure allows the temperature characteristics of the oscillation frequency of an oscillation circuit to be adjusted by a simple means.

### SUMMARY

An oscillation circuit according to the disclosure includes a first inverter configured so that temperature characteristics of a threshold voltage are adjustable; and a resistance element and a capacitor electrically connected to an input end and an output end of the first inverter, respectively.

### BRIEF DESCRIPTION OF THE DRAWINGS

FIG. 1 is a circuit diagram showing an example of the configuration of an oscillation circuit according to an embodiment of the disclosure.

FIG. 2 is a diagram showing an example of the detailed configuration around an inverter according to an embodiment of the disclosure.

FIG. 3 is a time chart showing an example of the signal waveforms of various parts during the operation of the oscillation circuit according to an embodiment of the disclosure.

FIG. 4 is a graph showing an example of the temperature characteristics of P+ polysilicon with a sheet resistance value of 500Ω/□.

FIG. 5 is a graph showing an example of the relationship between the threshold voltage ratio of the inverter and the oscillation frequency fluctuation rate.

FIG. 6 is a diagram showing an example of the waveform of the signal at the node n1 of the oscillation circuit 10.

FIG. 7 is a graph showing an example of the temperature characteristics of the threshold voltage of the inverter in the case where the resistance ratio (R_{vdd}:Rᵥₛₛ) between the resistance element R_{vdd} and the resistance element Rᵥₛₛ is set to 10:1.

FIG. 8 is a graph showing the simulation results of the temperature characteristics of the oscillation frequency.

FIG. 9A to FIG. 9K are diagrams showing variations of the means for adjusting the temperature characteristics of the threshold voltage of the inverter according to an embodiment of the disclosure.

FIG. 10 is a diagram showing an example of the configuration of the inverter in which the driving capability of N-MOS is adjustable according to an embodiment of the disclosure.

### DESCRIPTION OF THE EMBODIMENTS

An example of the embodiments of the disclosure will be described hereinafter with reference to the drawings. In addition, the same reference numerals are assigned to the same or equivalent components and parts in each drawing.

According to the disclosure, the temperature characteristics of the oscillation frequency of the oscillation circuit are adjustable by a simple means.

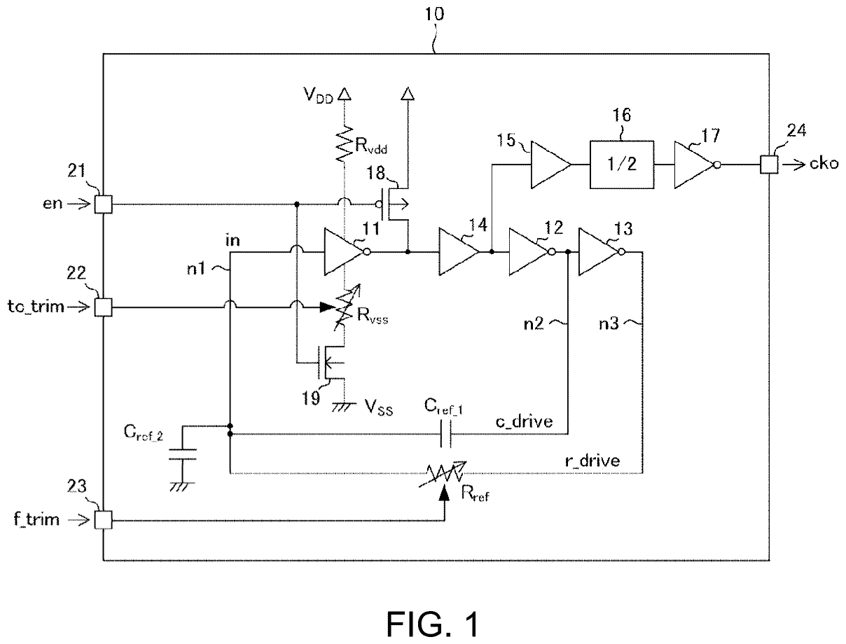

FIG. 1 is a circuit diagram showing an example of the configuration of an oscillation circuit 10 according to an embodiment of the disclosure. The oscillation circuit 10 is an integrated circuit provided on a semiconductor chip, and includes a plurality of inverters 11, 12, 13, and 17, a plurality of buffer circuits 14 and 15, a frequency divider circuit 16, a P-channel type MOSFET (hereinafter referred to as P-MOS) 18, an N-channel type MOSFET (hereinafter referred to as N-MOS) 19, resistance elements R_{vdd}, Rᵥₛₛ, and R_{ref}, and capacitors C_{ref_1} and C_{ref_2}.

The inverter 11, the buffer circuit 14, the inverter 12, and the inverter 13 are connected in series in this order. That is, the output end of the inverter 11 is connected to the input end of the buffer circuit 14, and the output end of the buffer circuit 14 is connected to the input end of the inverter 12. The output end of the inverter 12 is connected to the input end of the inverter 13. That is, the output signal of the inverter 11 is input to the inverter 12 via the buffer circuit 14, and the output signal of the inverter 12 is input to the inverter 13. The inverter 11 is an example of the “first inverter” in the disclosure. The inverter 12 is an example of the “second inverter” in the disclosure. The inverter 13 is an example of the “third inverter” in the disclosure. The output end of the inverter 12 is connected to one end of the capacitor C_{ref_1}, and the other end of the capacitor C_{ref_1} is connected to the input end of the inverter 11. The output end of the inverter 13 is connected to one end of the resistance element R_{ref}, and the other end of the resistance element R_{ref} is connected to the input end of the inverter 11. The resistance element R_{ref} is a variable resistance element, and has a resistance value that is settable by a trimming signal f_trim supplied to a control terminal 23. The oscillation frequency of the oscillation circuit 10 is adjustable by adjusting the resistance value of the resistance element R_{ref}.

The capacitor C_{ref_2} has one end connected to a node n1 at the input end of the inverter 11, and the other end connected to the ground line. The capacitor C_{ref_2} plays a role of determining a time constant together with the capacitor C_{ref_1}, and maintaining the potential of the node n1 at an intermediate potential between the potential V_{DD} of the power supply line and the potential Vss of the ground line.

One end of the resistance element Rudd is connected to the power supply line, and the other end is connected to the inverter 11. One end of the resistance element Rᵥₛₛ is connected to the inverter 11, and the other end is connected to the drain of the N-MOS 19. The resistance element Rᵥₛₛ is a variable resistance element, and has a resistance value that is settable by a trimming signal tc_trim supplied via a control terminal 22. The trimming signal tc_trim is an example of the “control signal” in the disclosure. The N-MOS 19 has a source connected to the ground line and a gate connected to an enable terminal 21. The N-MOS 19 is turned on in response to a high-level enable signal en being supplied to the enable terminal 21, which enables the oscillation circuit 10.

The P-MOS 18 has a source connected to the power supply line, a drain connected to the output end of the inverter 11, and a gate connected to the enable terminal 21. The P-MOS 18 is turned off in response to the high-level enable signal en being supplied via the enable terminal 21, which enables the oscillation circuit 10. The trimming signals tc_trim and f_trim and the enable signal en are respectively supplied from outside the semiconductor chip on which the oscillation circuit 10 is formed. Nevertheless, the trimming signals tc_trim and f_trim and the enable signal en may be generated in a circuit formed within the semiconductor chip.

The output end of the buffer circuit 14 is also connected to the input end of the buffer circuit 15. The output end of the buffer circuit 15 is connected to the input end of the frequency divider circuit 16, and the output end of the frequency divider circuit 16 is connected to the input end of the inverter 17. The output end of the inverter 17 is connected to an output terminal 24. The output signal of the inverter 11 is input to the frequency divider circuit 16 via the buffer circuits 14 and 15, and after the frequency is halved (½), the signal is inverted by the inverter 17. The output signal of the inverter 17 is output from the output terminal 24 as an oscillation output signal cko.

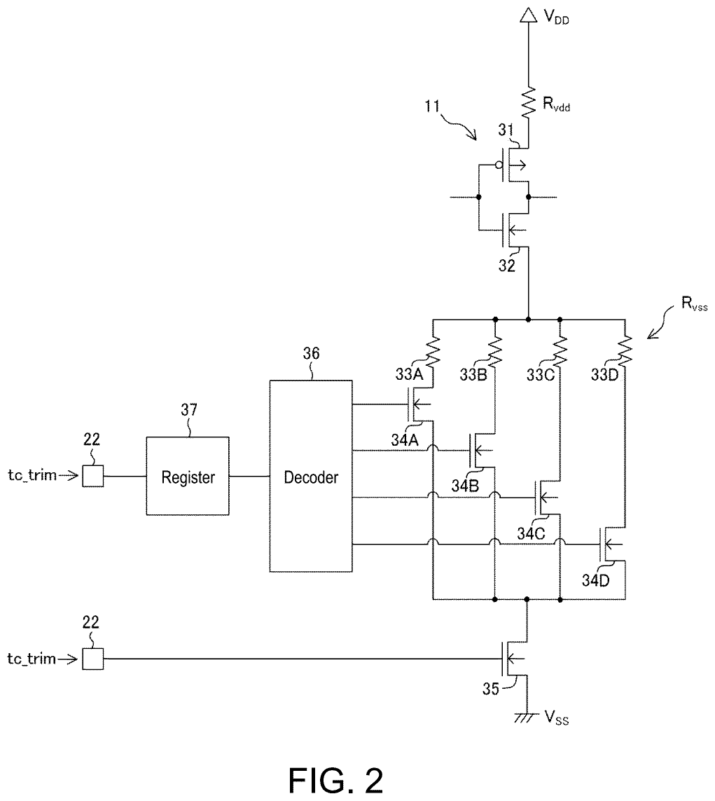

FIG. 2 is a diagram showing an example of the detailed configuration around the inverter 11. The inverter 11 is composed of a CMOS circuit that includes a P-MOS 31 and an N-MOS 32. The resistance element Rudd has one end connected to the power supply line, and the other end connected to the source of the P-MOS 31. The resistance element Rᵥₛₛ, which is a variable resistance element, includes a plurality of resistance elements 33A, 33B, 33C, and 33D, each of which has one end connected to the source of the N-MOS 32. The other ends of the resistance elements 33A to 33D are connected to the drains of the N-MOSs 34A, 34B, 34C, and 34D, respectively. The gates of the N-MOSs 34A to 34D are connected to a decoder 36, and the sources are connected to the drain of the N-MOS 35. The N-MOSs 34A to 34D are selectively turned on by a decode signal supplied from the decoder 36. In response to the N-MOSs 34A to 34D being turned on, the corresponding resistance elements 33A to 33D are enabled. The resistance value of the resistance element R_{vdd} is settable by selectively turning on the N-MOSs 34A to 34D.

The resistance setting value indicated by the trimming signal tc_trim supplied via the control terminal 22 is stored in a register 37. The decoder 36 supplies a decode signal according to the resistance setting value stored in the register 37 to the N-MOSs 34A to 34D.

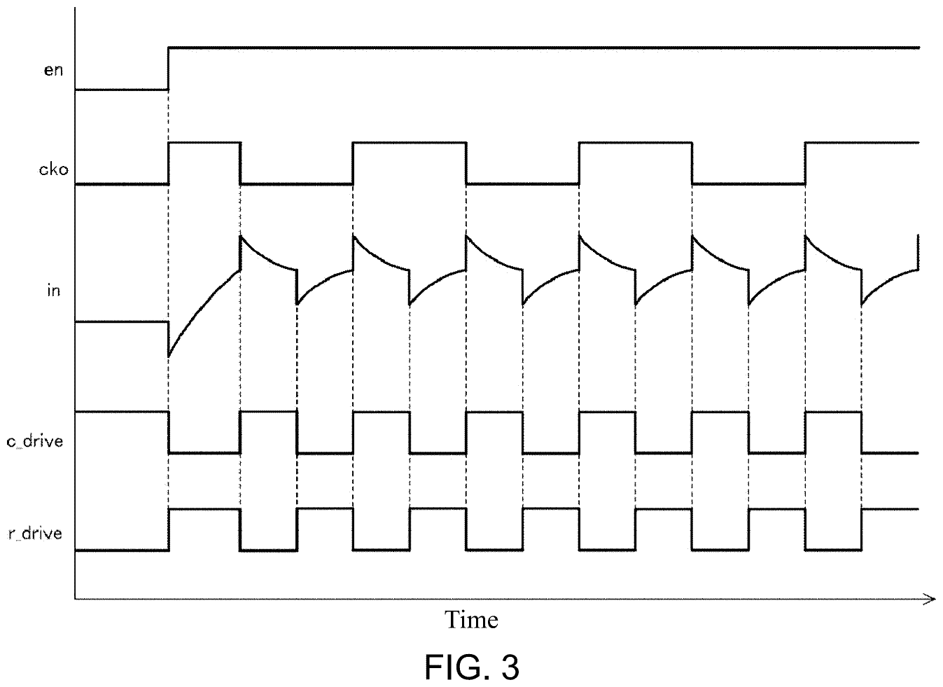

FIG. 3 is a time chart showing an example of the signal waveforms of various parts during the operation of the oscillation circuit 10. FIG. 3 shows the enable signal en, the oscillation output signal cko, the signal in at the node n1 at the input end of the inverter 11, the signal c_drive at the node n2 at the output end of the inverter 12, and the signal r_drive at the node n3 at the output end of the inverter 13. The oscillation output signal cko of a constant frequency is output from the output terminal 24 of the oscillation circuit 10. The signals c_drive and r_drive have opposite logic levels, and the frequency of these signals is twice the frequency of the oscillation output signal cko.

The oscillation frequency of the oscillation circuit 10 depends on the capacitance of the capacitor C_{ref_1} and the resistance value of the resistance element R_{ref}. Therefore, the temperature characteristics of the oscillation frequency depend on the temperature characteristics of the resistance element R_{ref} and the capacitor C_{ref_1}. While the temperature characteristics of the capacitor C_{ref_1} are generally flat, the temperature characteristics of the resistance element R_{ref} fluctuate by several percent within an operating temperature range (for example, −40° C. to 120° C.). Nevertheless, the temperature characteristics of the capacitor C_{ref_1} may not be flat and may have a slight slope.

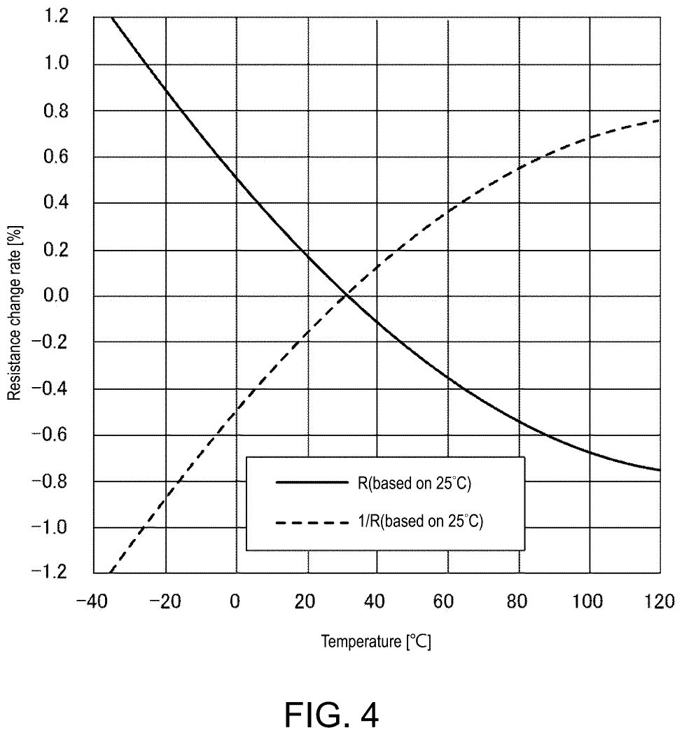

FIG. 4 is a graph showing an example of the temperature characteristics of P+ polysilicon with a sheet resistance value of 500Ω/□, which constitutes the resistance element R_{ref}. In FIG. 4, the solid line indicates the temperature characteristics of the resistance value R of the resistance element R_{ref}, and the dotted line indicates the temperature characteristics of the reciprocal 1/R of the resistance value. In the graph shown in FIG. 4, the resistance change rate is based on the value at 25° C. If the temperature characteristics of the resistance element R_{ref} are directly reflected in the temperature characteristics of the oscillation frequency of the oscillation circuit 10, the oscillation frequency may fluctuate by several percent within the operating temperature range (for example, −40° C. to 120° C.). Therefore, this type of oscillation circuit is not suitable for use in applications (for example, communication applications) that have strict requirements for the temperature characteristics of the oscillation frequency.

The oscillation circuit 10 according to this embodiment allows the temperature characteristics of the threshold voltage Vₜₕ of the inverter 11 to be adjusted by adjusting the resistance value of the resistance element Rᵥₛₛ, which is a variable resistance element. Therefore, the temperature characteristics of the resistance element R_{ref}, which determine the temperature characteristics of the oscillation frequency of the oscillation circuit 10, are canceled by the temperature characteristics of the threshold voltage Vₜₕ of the inverter 11, thereby making the temperature characteristics of the oscillation frequency of the oscillation circuit 10 close to flat. The following describes in detail adjustment of the temperature characteristics of the threshold voltage Vₜₕ of the inverter 11.

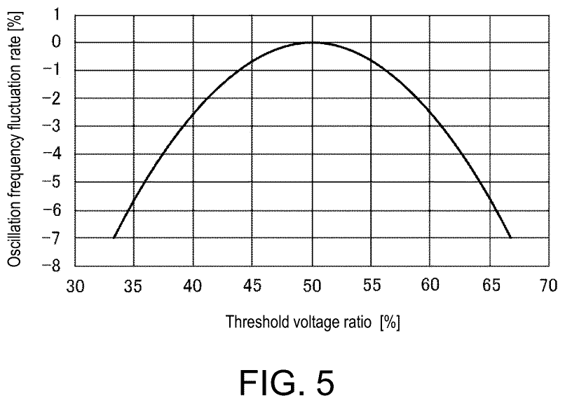

The oscillation frequency of the oscillation circuit 10 changes according to the threshold voltage Vₜₕ of the inverter 11. FIG. 5 is a graph showing an example of the relationship between the threshold voltage ratio of the inverter and the oscillation frequency fluctuation rate. The threshold voltage ratio is expressed as a ratio of the threshold voltage Vₜₕ of the inverter 11 to the potential V_{DD} of the power supply line. For example, a threshold voltage ratio of 50% means that the threshold voltage Vₜₕ of the inverter 11 is 0.5 V_{DD}. The oscillation frequency fluctuation rate is a fluctuation rate of oscillation frequency based on the oscillation frequency at the threshold voltage ratio of 50%. The oscillation frequency of the oscillation circuit 10 becomes highest when the threshold voltage ratio is 50%, and becomes lower as the deviation from the threshold voltage ratio of 50% increases. For example, in the case where Vₜₕ=0.67 V_{DD}, the oscillation frequency of the oscillation circuit 10 is approximately 7% lower than in the case where Vₜₕ=0.5 V_{DD}.

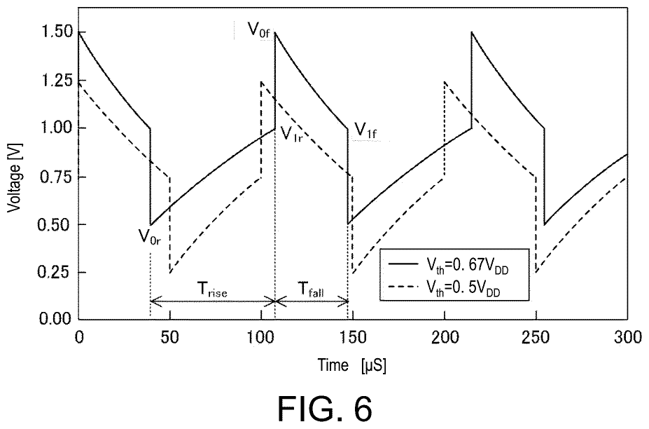

FIG. 6 is a diagram showing an example of the waveform of the signal in at the node n1 of the oscillation circuit 10. In FIG. 6, the dotted line indicates the case where Vₜₕ=0.5 V_{DD}, and the solid line indicates the case where Vₜₕ=0.67 V_{DD}. In the case where Vₜₕ=0.67 V_{DD}, compared to the case where Vₜₕ=0.5 V_{DD}, the rise time Tᵣᵢₛₑ for the potential of the node n1 to rise from the inflection point V₀ᵣ to the inflection point V₁ᵣ increases, and the fall time T_{fall} for the potential to fall from the inflection point V₀ᵣ to the inflection point V_{1f} decreases.

The result of calculation of the oscillation frequency fluctuation rate in the case where Vₜₕ=0.67 V_{DD} is shown below. Here, T₁ is the oscillation period in the case where Vₜₕ=0.75 V, and T₂ is the oscillation period in the case where Vₜₕ=1.00 V.

$${T}_{rise} = - {C}_{ref} \times {R}_{ref} \times ln ( {V}_{1 r} \div {V}_{0 r} ) = - {C}_{ref} \times {R}_{ref} \times ln ( \frac{{V}_{DD} - {V}_{th}}{{V}_{DD} - {V}_{th} + a} ) \qquad [ Formula 1 ]$$

$${T}_{fall} = - {C}_{ref} \times {R}_{ref} \times ln ( {V}_{1 f} \div {V}_{0 f} ) = - {C}_{ref} \times {R}_{ref} \times ln ( \frac{{V}_{th}}{{V}_{th} + a} )$$

$$Period T = {T}_{rise} + {T}_{fall} = - {C}_{ref} \times {R}_{ref} \times ln ( \frac{{V}_{DD} - {V}_{th}}{{V}_{DD} - {V}_{th} + a} \times \frac{{V}_{th}}{{V}_{th} + a} )$$

$$Frequency f = \frac{1}{T}$$

$$a = \frac{{C}_{ref \_ main}}{{C}_{ref \_ main} + {C}_{ref \_ att}} \times {V}_{DD}$$

$$In the case of {V}_{DD} = 1.5 V , {V}_{t h} = 0.75 V , \\ a = \frac{C}{3 C} \times 1.5 = 0.5 V , {T}_{1} = 1.0 \; 216 {C}_{ref} {R}_{ref}$$

$$In the case of {V}_{DD} = 1.5 V , {V}_{t h} = 1. V , \\ a = \frac{C}{3 C} \times 1.5 = 0.5 V , {T}_{2} = 1.0 \; 986 {C}_{ref} {R}_{ref}$$

$$\frac{{f}_{2}}{{f}_{1}} = \frac{{T}_{1}}{{T}_{2}} ≐ 0.93 ⇒ - 7 \%$$

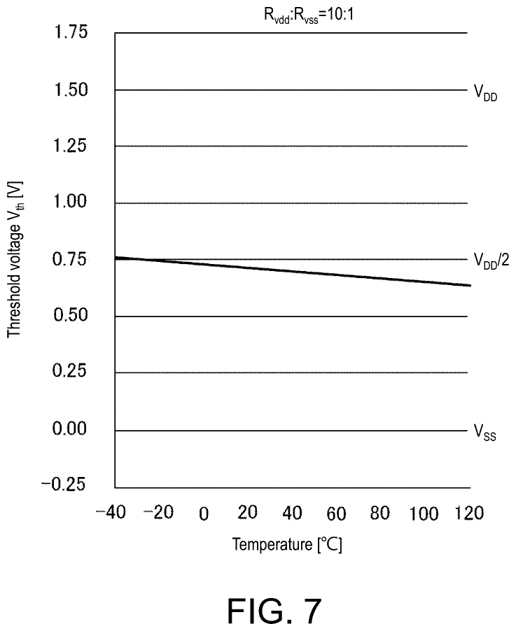

In the case where the resistance values of the resistance element R_{vdd} and the resistance element Rᵥₛₛ are sufficiently large with respect to the driving capability of the inverter 11, the temperature characteristics of the threshold voltage Vₜₕ of the inverter 11 depend on the ratio of the resistance element R_{vdd} to the resistance element Rᵥₛₛ. For example, by setting the resistance value of the resistance element Rᵥₛₛ smaller than the resistance element R_{vdd}, the contribution of the N-MOS 32 (see FIG. 2) to the driving capability on the ground side of the inverter 11 increases, so the threshold voltage Vₜₕ of the inverter 11 has negative temperature characteristics. FIG. 7 is a graph showing an example of the temperature characteristics of the threshold voltage Vₜₕ of the inverter 11 in the case where the resistance ratio (R_{vdd}:Rᵥₛₛ) between the resistance element R_{vdd} and the resistance element Russ is set to 10:1.

The temperature characteristics of the threshold voltage Vₜₕ of the inverter 11 are adjustable by changing the resistance value of the resistance element Rᵥₛₛ, which is a variable resistance element, and by changing the resistance ratio between the resistance element R_{vdd} and the resistance element Rᵥₛₛ. In order to cancel the temperature characteristics of the resistance element R_{ref}, which determine the temperature characteristics of the oscillation frequency of the oscillation circuit 10, the temperature characteristics of the threshold voltage Vₜₕ of the inverter 11 may be adjusted, thereby making the temperature characteristics of the oscillation frequency of the oscillation circuit 10 close to flat.

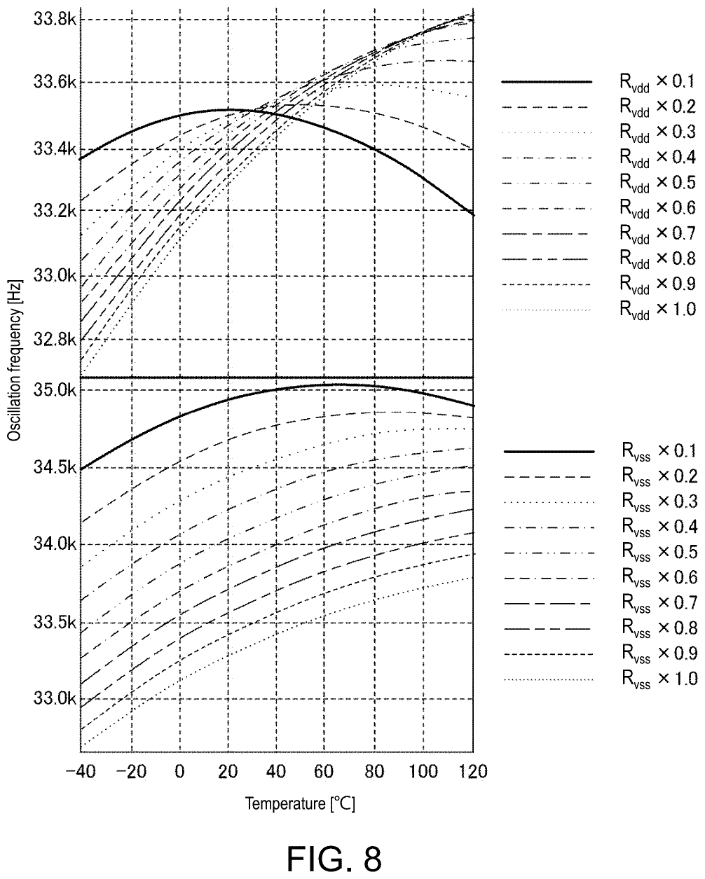

The upper part of FIG. 8 is a graph showing simulation results of the temperature characteristics of the oscillation frequency of the oscillation circuit 10 in the case where the ratio of the resistance value of the resistance element R_{vdd} to the resistance element Rᵥₛₛ was changed. In FIG. 8, for example, “R_{vdd}×0.1” means R_{vdd}:Rᵥₛₛ=1:10, and “R_{vdd}×1” means R_{vdd}:Rᵥₛₛ=1:1. The lower part of FIG. 8 is a graph showing simulation results of the temperature characteristics of the oscillation frequency of the oscillation circuit 10 in the case where the ratio of the resistance value of the resistance element Russ to the resistance element R_{vdd} was changed. In FIG. 8, for example, “Rᵥₛₛ×0.1” means R_{vdd}:Rᵥₛₛ=10:1, and “Rᵥₛₛ×1” means R_{vdd}:Rᵥₛₛ=1:1. As the ratio of the resistance value of the resistance element R_{vdd} to the resistance element Rᵥₛₛ is decreased and as the ratio of the resistance value of the resistance element Russ to the resistance element R_{vdd} is decreased, the temperature characteristics of the oscillation frequency tend to become flat.

For example, by adjusting the resistance value of the resistance element Russ to R_{vdd}:Rᵥₛₛ=10:1, the contribution of the N-MOS to the driving capability on the ground side of the inverter 11 increases, so the threshold voltage Vₜₕ of the inverter 11 has negative temperature characteristics. In this case, according to FIG. 7, the threshold voltage Vₜₕ (0.75 V) at −40° C. is about 50% of V_{DD} (1.5 V), and the threshold voltage Vₜₕ (0.63 V) at 120° C. is about 42% of V_{DD} (1.5 V). When the change in threshold voltage Vₜₕ due to this temperature change is converted into a change in oscillation frequency using the graph shown in FIG. 5, it is about −2%. That is, by adjusting the resistance value of the resistance element Rᵥₛₛ to R_{vdd}:Rᵥₛₛ=10:1, the oscillation frequency of the oscillation circuit 10 may have temperature characteristics of about −2%.

On the other hand, the resistance value of the resistance element R_{ref} changes by about +2% with respect to the temperature change from −40° ° C. to 120° C. By setting R_{vdd}:Rᵥₛₛ=10:1, the temperature characteristics of the resistance element R_{ref} are canceled by the temperature characteristics of the threshold voltage Vₜₕ of the inverter 11, and the temperature characteristics of the oscillation frequency of the oscillation circuit 10 become flat. In this way, the oscillation circuit 10 according to this embodiment is capable of making the temperature characteristics of the oscillation frequency close to flat by adjusting the resistance value of the resistance element Rᵥₛₛ.

Due to manufacturing variations in the circuit elements constituting the oscillation circuit 10, the resistance ratio (R_{vdd}:Rᵥₛₛ) at which the temperature characteristics of the oscillation frequency of the oscillation circuit 10 become flat differs for each individual oscillation circuit 10. Therefore, it is preferable to adjust the resistance value of the resistance element Rᵥₛₛ for each individual oscillation circuit 10 in order to flatten the temperature characteristics of the oscillation frequency of the oscillation circuit 10. The resistance value of the resistance element Rᵥₛₛ may be adjusted, for example, as follows.

A plurality of oscillation frequency measurement points are determined within the operating temperature range of the oscillation circuit 10. For example, in the case where the operating temperature range is −40° ° C. to 120° ° C., the measurement points may be, for example, three points: −40° C., 25° C., and 85° C. At each measurement point, the oscillation frequency of the oscillation circuit 10 is measured while changing the resistance value of the resistance element Rᵥₛₛ using the trimming signal tc_trim. The resistance value of the resistance element Rᵥₛₛ at which the difference in the oscillation frequency between the plurality of measurement points is the smallest (that is, the temperature characteristics of the oscillation frequency are the flattest) is determined as the resistance setting value, and the resistance setting value is stored in the register 37. Thereafter, in the oscillation circuit 10, the resistance value of the resistance element Rᵥₛₛ is set to the resistance setting value stored in the register 37.

As described above, the oscillation circuit 10 according to the disclosure includes the inverter 11, the inverter 12 to which the output signal of the inverter 11 is input, and the inverter 13 to which the output signal of the inverter 12 is input. The oscillation circuit 10 includes the resistance element R_{ref} having one end connected to the output end of the inverter 13 and the other end connected to the input end of the inverter 11, and the capacitor C_{ref_1} having one end connected to the output end of the inverter 12 and the other end connected to the input end of the inverter 11. In the oscillation circuit 10, the temperature characteristics of the threshold voltage Vₜₕ of the inverter 11 are configured to be adjustable. The oscillation circuit 10 according to this embodiment is capable of adjusting the temperature characteristics of the oscillation frequency in the oscillation circuit 10 by the temperature characteristics of the threshold voltage Vₜₕ of the inverter 11. The temperature characteristics of the threshold voltage Vₜₕ of the inverter 11 are adjustable by adjusting the resistance value of the resistance element Rᵥₛₛ. That is to say, the oscillation circuit 10 according to this embodiment is capable of adjusting the temperature characteristics of the oscillation frequency of the oscillation circuit 10 by a simple means.

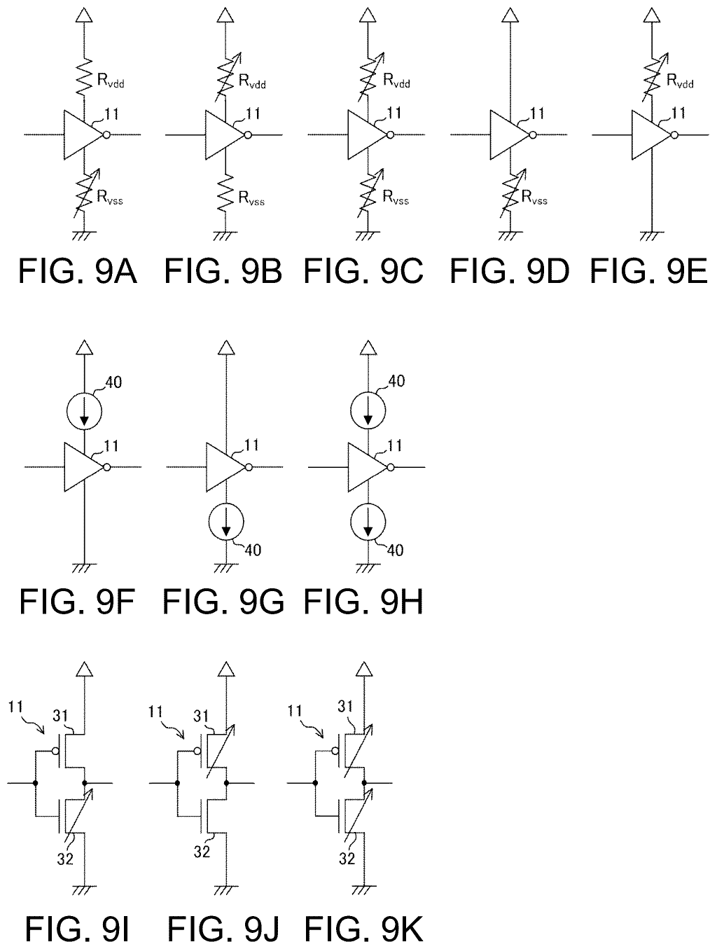

Although the above illustrates a case where the temperature characteristics of the threshold voltage Vₜₕ of the inverter 11 are adjusted by the resistance value of the resistance element Russ, the disclosure is not limited to this aspect. FIG. 9A to FIG. 9K are diagrams showing variations of the means for adjusting the temperature characteristics of the threshold voltage Vₜₕ of the inverter 11. As shown in FIG. 9A to FIG. 9C, the temperature characteristics of the threshold voltage Vₜₕ of the inverter 11 may be adjusted by the resistance value of at least one of the resistance elements R_{vdd} and Rᵥₛₛ. As shown in FIG. 9D and FIG. 9E, the oscillation circuit 10 may include only one of the resistance elements R_{vdd} and Rᵥₛₛ with a variable resistance value.

Furthermore, as shown in FIG. 9F to FIG. 9H, the temperature characteristics of the threshold voltage Vₜₕ of the inverter 11 may be adjusted by a current source 40 that controls the current flowing through the inverter 11. The threshold voltage Vₜₕ of the inverter 11 depends on the current value of the bias current supplied from the current source 40. Therefore, the temperature characteristics of the threshold voltage Vₜₕ of the inverter 11 may be changed by changing the temperature characteristics of the current value of this bias current. The current source 40 is provided on at least one of the power supply line side and the ground line side.

The current source 40 may include, for example, a bandgap circuit (not shown) that outputs an output voltage with adjusted temperature dependence, and a variable resistance element (not shown), and may convent the voltage output from the bandgap circuit into a current according to the resistance value of the variable resistance element, and output the converted current as a bias current. The current source 40 may correspond to, for example, the voltage-current conversion circuit described in Japanese Patent No. 5882606. The temperature characteristics of the bias current are adjustable by the resistance value of the variable resistance element. Thus, adjusting the resistance value of the variable resistance element using a control signal supplied from the outside allows the temperature characteristics of the bias current to be adjusted.

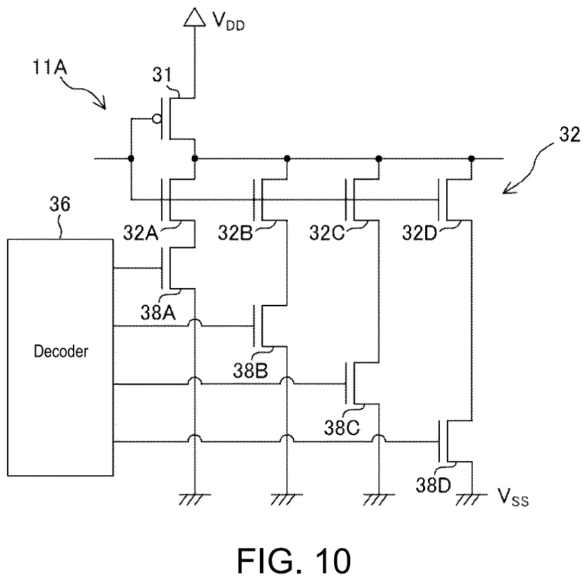

Furthermore, as shown in FIG. 9I to FIG. 9K, the temperature characteristics of the threshold voltage Vₜₕ of the inverter 11 may be adjusted by the driving capabilities of the P-MOS 31 and the N-MOS 32 that constitute the inverter 11. The temperature characteristics of the threshold voltage Vₜₕ of the inverter 11 may be changed by changing the balance between the driving capabilities of the P-MOS 31 and the N-MOS 32. FIG. 10 is a diagram showing an example of the configuration of an inverter 11A in which the driving capability of the N-MOS 32 is adjustable. In the inverter 11A, the N-MOS 32 includes a plurality of N-MOSs 32A, 32B, 32C, and 32D. N-MOSs 38A, 38B, 38C, and 38D are connected in series to the N-MOSs 32A to 32D, respectively. The N-MOSs 38A to 38D are selectively turned on by a decode signal supplied from the decoder 36. In response to the N-MOSs 38A to 38D being turned on, the corresponding N-MOSs 32A to 32D are enabled. Enabled N-MOSs 32A to 32D are connected in parallel to each other. The driving capability of the N-MOS 32 increases as the number of N-MOSs 32A to 32D that are enabled increases. Which of the N-MOSs 32A to 32D is/are enabled is determined so as to make the temperature characteristics of the oscillation frequency of the oscillation circuit 10 flat. Regarding the above embodiments, the following appendixes are further disclosed.

### Appendix 1

An oscillation circuit, comprising:
a first inverter configured so that temperature characteristics of a threshold voltage are adjustable; and
a resistance element and a capacitor electrically connected to an input end and an output end of the first inverter, respectively.

### Appendix 2

The oscillation circuit according to Appendix 1, further comprising:
a second inverter to which an output signal of the first inverter is input; and
a third inverter to which an output signal of the second inverter is input,
wherein the resistance element has one end connected to an output end of the third inverter, and the other end connected to the input end of the first inverter, and
the capacitor has one end connected to an output end of the second inverter, and the other end connected to the input end of the first inverter.

### Appendix 3

The oscillation circuit according to Appendix 1 or 2, comprising a control terminal to which a control signal for adjusting the temperature characteristics of the threshold voltage of the first inverter is input.

### Appendix 4

The oscillation circuit according to any one of Appendixes 1 to 3, comprising at least one variable resistance element for adjusting the temperature characteristics of the threshold voltage of the first inverter, wherein a resistance value of the variable resistance element is settable by a control signal.

### Appendix 5

The oscillation circuit according to Appendix 4, wherein the first inverter comprises a CMOS circuit that comprises a P-channel type transistor and an N-channel type transistor, and the variable resistance element is connected to at least one of a source of the P-channel type transistor and a drain of the N-channel type transistor.

### Appendix 6

The oscillation circuit according to any one of Appendixes 1 to 3, comprising at least one current source that supplies a bias current for the first inverter, wherein temperature characteristics of the bias current are adjustable by a control signal.

### Appendix 7

The oscillation circuit according to any one of Appendixes 1 to 3, wherein the first inverter comprises a CMOS circuit that comprises a P-channel type transistor and an N-channel type transistor, and
a driving capability of at least one of the P-channel type transistor and the N-channel type transistor is settable by a control signal supplied from outside.

What is claimed is:

1. An oscillation circuit, comprising:
a first inverter configured so that temperature characteristics of a threshold voltage are adjustable; and
a resistance element and a capacitor electrically connected to an input end and an output end of the first inverter, respectively.

2. The oscillation circuit according to claim 1, further comprising:
a second inverter to which an output signal of the first inverter is input; and
a third inverter to which an output signal of the second inverter is input,
wherein the resistance element has one end connected to an output end of the third inverter, and the other end connected to the input end of the first inverter, and
the capacitor has one end connected to an output end of the second inverter, and the other end connected to the input end of the first inverter.

3. The oscillation circuit according to claim 1, comprising a control terminal to which a control signal for adjusting the temperature characteristics of the threshold voltage of the first inverter is input.

4. The oscillation circuit according to claim 1, comprising at least one variable resistance element for adjusting the temperature characteristics of the threshold voltage of the first inverter, wherein a resistance value of the variable resistance element is settable by a control signal.

5. The oscillation circuit according to claim 4, wherein the first inverter comprises a CMOS circuit that comprises a P-channel type transistor and an N-channel type transistor, and
the variable resistance element is connected to at least one of a source of the P-channel type transistor and a drain of the N-channel type transistor.

6. The oscillation circuit according to claim 1, comprising at least one current source that supplies a bias current for the first inverter,
wherein temperature characteristics of the bias current are adjustable by a control signal.

7. The oscillation circuit according to claim 1, wherein the first inverter comprises a CMOS circuit that comprises a P-channel type transistor and an N-channel type transistor, and
a driving capability of at least one of the P-channel type transistor and the N-channel type transistor is settable by a control signal.
